(19) United States
(12) Patent Application Publication
(10) Pub. No.: US 2004/0212050 A1
(43) Pub. Date: Oct. 28, 2004

(54) Film carrier tape for mounting an electronic part, process for producing the same, and screen for solder resist coating

(75) Inventors: Nobuaki Fujii, Yamaguchi (JP); Yutaka Iguchi, Tokyo (JP)

Correspondence Address: Kent E. Baldauf, 700 Koppers Building, 436 Seventh Avenue, Pittsburgh, PA, 15219-1818, US

(73) Assignee: MITSUI MINING & SMELTING CO., LTD.

(21) Appl. No.: 10/831,640

(22) Filed: Apr. 23, 2004

(30) Foreign Application Priority Data
Apr. 25, 2003 (JP) 2003-122524
May 8, 2003 (JP) 2003-130693
May 13, 2003 (JP) 2003-135048

(51) Int. Cl. H01L 23/495

(52) U.S. Cl. 257/668

(57) ABSTRACT

A film carrier tape for mounting an electronic part, comprising an insulating film, a wiring pattern formed on a surface of the insulating film and a solder resist layer formed on the wiring pattern except connecting lead portions of the wiring pattern, wherein the solder resist coating thickness at the edge portion of the solder resist layer is continuously decreased toward the tip of the edge portion. The film carrier tape for mounting an electronic part can be produced by applying a solder resist coating solution onto the wiring pattern using a screen in which opening sizes at the edge portion of a coating solution passing zone are reduced stepwise or continuously or by applying a solder resist coating solution onto the wiring pattern with pressing a film carrier against the screen so as to decrease a coating weight of the solder resist coating solution continuously or stepwise toward the tip of the edge portion of the resulting solder resist layer. Also disclosed is a screen for solder resist coating, comprising a gauze having an area in which opening sizes are changed stepwise or continuously.

### FIELD OF THE INVENTION

The present invention relates to film carrier tapes for mounting electronic part which hardly cause mounting failures when electronic parts are mounted thereon, a process for producing the same, and a screen for solder resist coating used for producing the film carrier tapes for mounting electronic part. In the present invention, the film carrier tapes for-mounting electronic part include TAB (tape automated bonding) tape, BGA (ball grid array), CSP (chip size package), COF (chip on film), FPC (flexible print circuit), double-sided wiring tape and multi-layer wiring tape, etc.

### BACKGROUND OF THE INVENTION

For mounting electronic parts such as IC, film carrier tapes for mounting electronic part, such as TAB tape, BGA and CSP, have been employed. In such film carrier tapes for mounting electronic part, a wiring pattern made of a conductive metal is formed on a surface of an insulating film, and in the use of the film carrier tapes, one end portion (inner lead) of the wiring pattern is bonded to a bump of an electronic part and the other end portion (outer lead) of the wiring pattern is bonded to an electronic equipment.

Therefore, after the wiring pattern is formed, the outer lead and the inner lead need to be exposed because they are used for bonding, but because other portions are not directly used for bonding, a solder resist layer is formed thereon to protect them. The solder resist layer is formed by selectively coating the wiring pattern with a solder resist coating solution usually containing a thermosetting resin by the use of a screen mask (screen for solder resist coating) so as to expose the lead portions and curing the coating solution. As shown in FIG. 10, the screen mask used herein comprises, for example, a frame 101 and a gauze 102 stretched on the frame 101, and a surface of the gauze is provided with a coating solution passing zone 103 in a desired shape. The solder resist coating solution passes through the coating solution passing zone 103 and is applied to a surface of the wiring pattern, while other area 104 than the coating solution passing zone 103 is masked.

The gauze 102 of the screen mask for solder resist coating is a net constituted of metal fine wires or the like, and the metal fine wires to constitute the gauze are, for example, stainless steel fine wires having the same diameters so that the solder resist coating solution can uniformly passes through the coating solution passing zone formed in the screen mask. Accordingly, the amount of the solder resist coating solution that passes through the coating solution passing zone of the screen mask is desired to be equal at any part of the coating solution passing zone, and the screen mask is generally produced so as to make the thickness of the resulting solder resist layer uniform.

However, it has been found that, in case of bonding the film carrier to a transparent conductive (e.g., Indium Tin Oxide) of a liquid crystal panel by means of an anisotropic conductive film (ACF) or in case of bonding the film carrier to a functional device by soldering, the film carrier sometimes slightly deviates to thereby make the bonding portion slightly overlap the solder resist layer, and as a result, a problem that the bonding is hindered by the thickness of the solder resist layer takes place. That is to say, from the viewpoint of the proper purpose of the solder resist layer to protect the wiring pattern, it is desirable to form a uniform and thick solder resist layer as a whole, but taking positioning error in the bonding into consideration, the thickness of the solder resist layer is desired to be small in the vicinity of the leads.

In order to make the thickness of the solder resist layer in the vicinity of the leads small and the thickness of the residual portion of the solder resist layer large, the following process is employable. That is to say, a thin solder resist layer is formed first, and then a solder resist coating solution is further applied onto the center portion of the wiring pattern using a screen mask having a masking zone near the lead. By the use of this process, the resulting solder resist layer can have a difference in its thickness. In this process, however, the solder resist coating solution needs to be applied twice, and this brings about a problem of poor productivity. Further, a difference in level is made at the boundary between the solder resist layer near the lead formed by coating of one time and the solder resist layer formed by coating of two times, and if the resulting film carrier is bent, stress is concentrated to sometimes cause breaking of wire, or bending of the film carrier sometimes becomes difficult in itself.

In Japanese Patent Laid-Open Publication No. 171253/1994, there are disclosed an invention of a screen comprising a gauze and an emulsion wherein at least a part of the gauze through which an ink passes is removed and an invention of a process for producing a film carrier using the screen.

By the use of the screen wherein a part of the gauze is removed as above, a coating of the solder resist ink can be imparted with different thickness, but removal of a part of the gauze brings about a new problem that durability of the whole screen is markedly lowered.

### OBJECT OF THE INVENTION

It is an object of the present invention to provide a film carrier tape for mounting electronic part, which is reduced in occurrence of connection failures.

It is another object of the present invention to provide a process for producing a film carrier tape for mounting electronic part, which is capable of reducing occurrence of connection failures.

It is a further object of the present invention to provide a screen used for producing the film carrier tape.

### SUMMARY OF THE INVENTION

The film carrier tape for mounting electronic part according to the present invention is a film carrier tape comprising an insulating film, a wiring pattern formed on a surface of the insulating film and a solder resist layer formed on the wiring pattern except connecting lead portions of the wiring pattern, wherein the solder resist coating thickness at the edge portion of the solder resist layer is continuously decreased toward the tip of the edge portion.

The film carrier tape for mounting electronic part of the present invention can be produced by a process comprising forming a desired wiring pattern on a surface of an insulating film and then forming a solder resist layer on the wiring pattern except lead portions of the wiring pattern, wherein formation of the solder resist layer is carried out by applying a solder resist coating solution using a screen for solder resist coating in which opening sizes at the edge portion of a coating solution passing zone are reduced stepwise or continuously.

The screen for solder resist coating for use in the present invention is a screen for solder resist coating which comprises a frame and a gauze stretched on the frame, wherein the gauze has an area in which opening sizes are changed stepwise or continuously.

The process for producing a film carrier tape for mounting electronic part according to the present invention comprises applying a solder resist coating solution onto a wiring pattern formed on a surface of an insulating film except connecting lead portions of the wiring pattern through a screen to form a solder resist layer, wherein application of the solder resist coating solution is carried out with pressing a film carrier against the screen so as to decrease a coating weight of the solder resist coating solution continuously or stepwise toward the tip of the edge portion of the resulting solder resist layer.

In the present invention, in order to press the film carrier against the screen, a protrusion to push up the film carrier so as to press it against the screen is preferably provided on a coating stage. The protrusion may be in a shape of a staircase.

By providing a protrusion on the coating stage to press the film carrier against the screen as described above, the amount of the solder resist coating solution fed to the pressed area is restricted, and hence, the thickness of the solder resist layer in said area can be continuously or stepwise decreased.

According to the process of the present invention, further, a solder resist layer having a slope where the solder resist coating thickness is continuously or stepwise decreased toward the tip can be formed by coating of one time.

In the film carrier tape for mounting electronic part produced by the process of the present invention, the thickness of the solder resist layer formed in the vicinity of the lead portion is continuously or stepwise decreased toward the edge, and hence, electrical connection of the film carrier to an electronic equipment such as a liquid crystal panel is not hindered by the thickness of the solder resist layer.

### BRIEF DESCRIPTION OF THE DRAWINGS

FIG. 1 is a group of sectional views to explain a process for producing a film carrier tape for mounting electronic part of the present invention, using an example of a section of a film carrier in each step of the process.

FIG. 2 is an enlarged sectional view showing an example of a section of an outer lead or inner lead portion.

FIG. 3 is a view schematically showing an example of a screen used in the present invention.

FIG. 4 is a schematic sectional view taken on line A-A of FIG. 3.

FIG. 5 is a view showing an example of a gauze at the edge portion of a coating solution passing zone.

FIG. 6 is a view schematically showing an example of a screen capable of stepwise decreasing an amount of a coating solution fed to a gauze positioned at the edge portion of the resulting solder resist layer near the lead to form a slope at the edge portion of the solder resist layer.

FIG. 7 is a group of sectional views to explain another embodiment of a process for producing a film carrier tape for mounting electronic part of the present invention, using an example a lengthwise section of a film carrier in each step of the process.

FIG. 8 is enlarged sectional views showing an example of a section of a coating stage having a protrusion that is used in the process of the present invention and an example of a section of a slope of a solder resist layer in the film carrier tape produced by the use of the coating stage.

FIG. 9 is enlarged sectional views showing an example of a section of a coating stage having a staircase protrusion that is used in the process of the present invention and an example of a section of a slope of a solder resist layer in the film carrier tape produced by the use of the staircase protrusion.

FIG. 10 is a view showing an example of a conventional screen for solder resist coating.

### DETAILED DESCRIPTION OF THE INVENTION

The film carrier tape for mounting electronic part of the present invention, the process for producing the film carrier tape and the screen for solder resist coating used in the present invention are described in detail hereinafter.

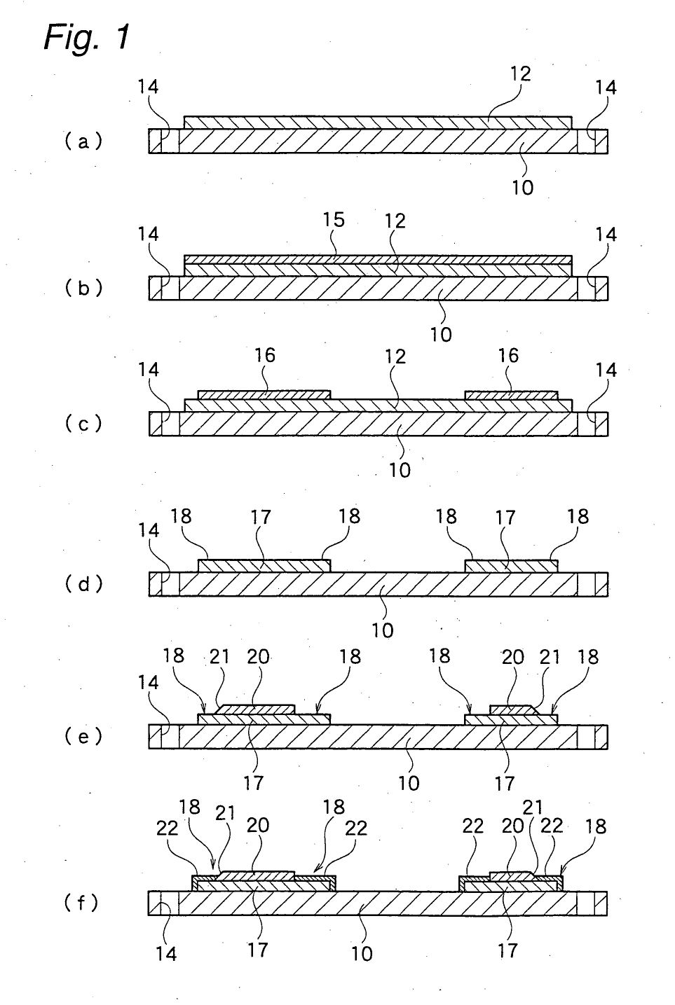

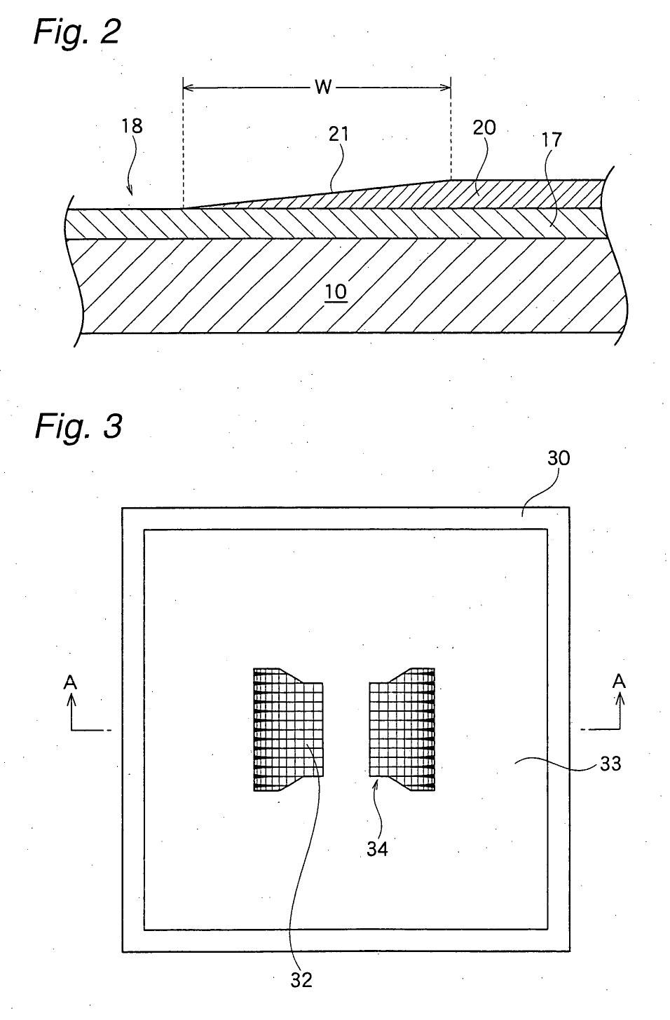

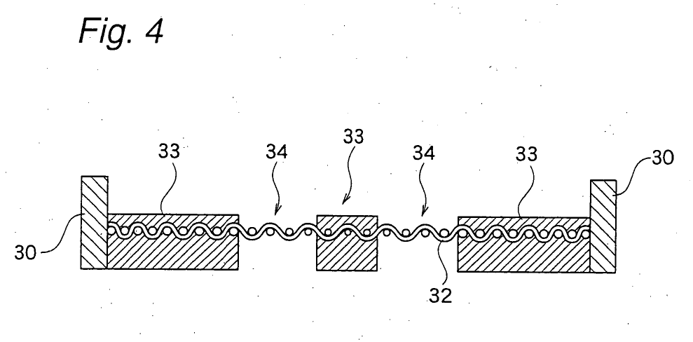

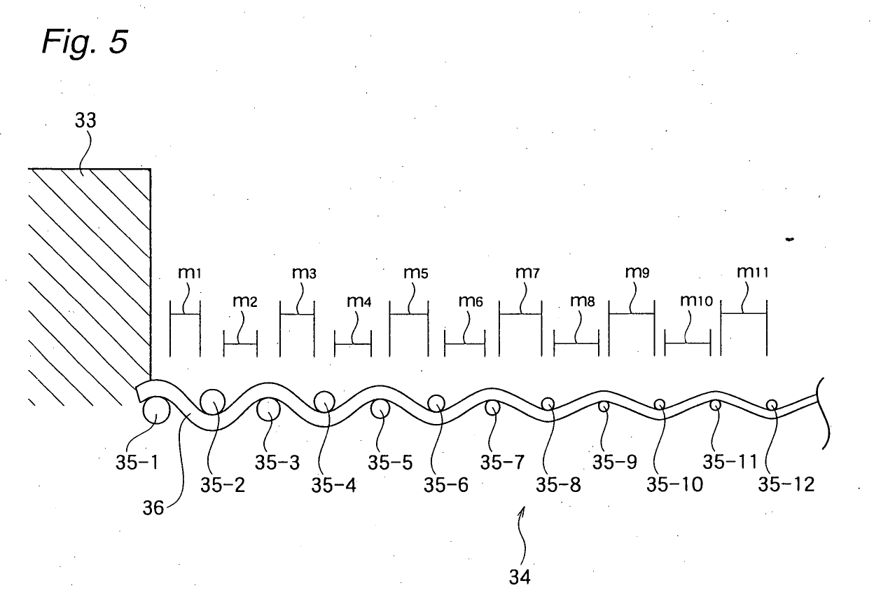

FIG. 1 is a group of sectional views to explain a process for producing the film carrier tape for mounting electronic part of the present invention, using an example of a section of a film carrier in each step of the process. FIG. 2 is an enlarged sectional view of a lead portion. FIG. 3 is a schematic view of a screen used in the present invention. FIG. 4 is a schematic sectional view taken on line A-A of FIG. 3. FIG. 5 is a view showing a gauze at the edge portion of a coating solution passing zone.

In the film carrier tape for mounting electronic part of the present invention, a wiring pattern 17 composed of a conductive metal foil 12 is formed on a surface of an insulating film 10, and at the end of the wiring pattern 17, a connecting lead 18 having a plated layer 22 is formed, as shown in FIG. 1(f). In the film carrier tape for mounting electronic part of the present invention, further, a solder resist layer 20 is formed except the connecting lead 18 so as to protect the wiring pattern 17. In the solder resist layer 20 formed on the wiring pattern 17 except the connecting lead 18, the edge portion near the connecting lead 18 is thinner than other portions, and a solder resist slope 21 where the thickness of the solder resist layer is continuously decreased toward the edge is formed.

Such a film carrier tape for mounting electronic part of the present invention can be produced in the following manner.

As shown in FIG. 1(a), the film carrier tape for mounting electronic part of the present invention is produced by the use of a composite laminate consisting of an insulating film 10 and a conductive metal layer 12 formed on a surface of the insulating film 10. As the insulating film 10, a synthetic resin film having excellent heat resistance, chemical resistance and heat/humidity stability can be employed. Examples of the synthetic resin films employable herein include a polyimide film, a polyamidoimide film, a heat-resistant polyester film, a BT resin film, a phenolic resin film and a liquid crystal polymer film. In the present invention, it is preferable to use a polyimide film showing prominently excellent heat resistance, chemical resistance and heat/humidity stability. On at least one surface of the insulting film 10 such as a polyimide film, a conductive metal layer 12 is formed. Examples of conductive metals employable for the conductive metal layer 12 include copper and aluminum. The conductive metal layer 12 may be directly provided on the surface of the insulating film 10 or may be formed by bonding a conductive metal foil to the surface of the insulating film 10 with an adhesive. Further, the conductive metal layer 12 may be a composite laminate obtained by a process comprising sputtering a metal such as nickel or chromium on the surface of the insulating film, then further sputtering a metal such as copper and depositing a conductive metal by plating to directly form a conductive metal layer on the insulating film. Also employable is a composite laminate obtained by a process comprising adding metal fine particles to a resin for forming an insulating film, forming an insulating film containing the metal fine particles, subjecting the insulating film to surface treatment to expose the metal fine particles contained in the film and depositing a conductive metal by means of plating technique using the metal fine particles as seed particles to form a conductive metal layer.

The thickness of the insulating film used in the present invention is in the range of usually 5 to 150 μm, preferably 5 to 125 μm, and the thickness of the conductive metal layer is in the range of usually 1 to 35 μm, preferably 8 to 35 μm. As the conductive metal, copper is preferably employed. Copper foils employable for forming the conductive metal layer include an electrodeposited copper foil and a rolled copper foil. For forming a wiring pattern by etching, an electrodeposited copper foil is preferably employed.

In the present invention, the conductive metal layer 12 may be formed on one surface of the insulating film 10 or may be formed on both surfaces of the insulating film 10. On the both side ends of the insulting film 10 in the width direction, sprocket holes 14 are formed in order to feed the film. In FIG. 1(a), a conductive metal layer is not formed on these widthwise ends of the insulating film where the sprocket holes are to be formed, but in the present invention, a conductive metal layer 12 may be formed all over the width of the insulting film 10. In this case, the sprocket holes 14 are usually formed by, for example, punching the conductive metal layer 12 and the insulating film 10 together after the conductive metal layer 12 is formed. By forming the conductive metal layer 12 around the sprocket holes 14 in this manner, the sprocket holes 14 are reinforced with the conductive metal layer 12, and hence the sprocket holes 14 can be prevented from deformation or breakage even when a thin polyimide film or the like is used as the insulating film 10.

The process of the present invention is applicable not only to production of a film carrier tape having device holes but also to a film carrier tape having no device hole.

In the present invention, a photoresist is applied to a surface of the conductive metal layer 12 arranged on at least one surface of the insulating film 10 to form a photoresist layer 15, as shown in FIG. 1(b). Then, the photoresist layer is exposed by light and developed to form a desired pattern 16 composed of the photoresist, as shown in FIG. 1(c). Then, using the desired pattern composed of the photoresist as a masking material, the conductive metal layer 12 provided on the surface of the insulating film 10 is subjected to etching to form a wiring pattern 17 having a shape corresponding to the pattern 16 as shown in FIG. 1(d). The end portion of the wiring pattern 17 thus formed is an inner lead or outer lead 18 which is to be bonded to a bump (not shown) of an electronic part or a lead of another member.

On the wiring pattern 17 formed as above, a solder resist layer 20 is formed except the lead 18, and the wires of the wiring pattern 17 except the lead 18 are protected by the solder resist layer 20.

From the viewpoint of protection of the wiring pattern 17, the thickness of the solder resist layer 20 is in the range of usually 1 to 75 μm, preferably 10 to 55 μm. By setting the thickness of the solder resist layer 20 in this range, a plating solution does not come onto the lower surface of the solder resist layer 20 in the subsequent plating step, and insulation between wires of the wiring pattern can be ensured. However, when an electronic part is mounted on the film carrier tape or when a film carrier tape having an electronic part mounted thereon is bonded to, for example, an ITO electrode of a liquid crystal panel, it is desirable that the thickness of the solder resist layer 20 near the lead 18 is not increased in order to ensure mounting of an electronic part or bonding between electrodes.

In the present invention, therefore, a solder resist layer having a prescribed thickness ranging from 1 to 75 μm, preferably from 10 to 55 μm, is formed on the wiring pattern 17 which is to be surely protected, similarly to the conventional solder resist layer, but in the vicinity of the lead 18, a slope 21 of the solder resist layer is formed. That is to say, the solder resist layer to constitute the film carrier tape for mounting electronic part of the present invention is formed in such a manner that the thickness of the edge portion of the solder resist layer in the vicinity of the lead 18 that is an end portion of the wiring pattern 17 should be continuously decreased toward the lead 18. FIG. 2 is a partial sectional view of a film carrier tape for mounting electronic part of the present invention, in which the coating thickness of the edge portion of the solder resist layer 20 is continuously decreased as the lead 18 is approached. As shown in FIG. 2, at the edge portion of the solder resist layer 20, a slope 21 of the solder resist layer where the coating thickness is continuously decreased toward the lead 18 is formed. 0.5 Although the width of the slope, 21 can be appropriately determined so as to surely make electrical connection of the film carrier, the width H of the slope 21 is in the range of usually 100 to 2000 μm, preferably 250 to 2000 μm, more preferably 300 to 1000 μm, particularly preferably 400 to 1000 μm.

In the present invention, the slope 21 at the edge portion of the solder resist layer 20 is formed by application of a solder resin coating solution one time using a screen for solder resist coating. The screen for solder resist coating for use in the present invention comprises a frame 30 and a gauze 32 stretched on the frame 30, as shown in FIG. 3 and FIG. 4.

A surface of the gauze 32 is coated with, for example, a photosensitive resin, and the photosensitive resin is exposed and developed to form a coating solution passing zone 34 that is unmasked. By allowing a solder resist coating solution to pass through the coating solution passing zone 34, a solder resist layer is formed on the prescribed portion of the wiring pattern. On the other hand, the area of the gauze 32 where the coating solution passing zone 34 is not provided is a masking zone 33 formed by a cured photosensitive resin or the like. The solder resist coating solution does not pass through the masking zone 33.

In the film carrier tape for mounting electronic part of the present invention, the solder resist layer has a slope 21, and the slope 21 can be formed by stepwise or continuously changing opening sizes of the corresponding part (corresponding to the slope 21) of the gauze of the screen for solder resist coating.

In the screen for solder resist coating, the gauze is constituted of metallic fine wires, synthetic fiber yarns or the like, and by stepwise or continuously reducing the sizes of the openings of the gauze through which the solder resist coating solution passes, the coating weight can be continuously or stepwise changed so as to form a slope, as shown in FIG. 2.

The screen for solder resist coating can be produced in the following manner. For example, a protective resin is applied onto the coating solution passing zone 34 formed in the screen in such a manner that a certain area of the gauze located nearest an outer lead and/or inner lead of a film carrier should be exposed, and plating is carried out on surfaces of stainless steel fine wires constituting the gauze to reduce opening sizes of the gauze constituted of the stainless steel fine wires in this area. Then, the protective resin is removed. Subsequently, a protective resin is applied again in such a manner that the above-plated area and a certain area inside the above-plated area should be exposed, and plating is carried out again on the first plated area and the area exposed this time to reduce opening sizes of the gauze. After the plating of the second time is carried out as above, the protective resin is removed. Subsequently, application of a protective resin and plating are carried out again in the same manner as described above to further reduce opening sizes of the stainless steel fine wires of the gauze. By repeating stepwise plating of the stainless steel fine wires as above, opening sizes of the gauze can be controlled. For example, if plating of a gauze having an opening size of about 100 μm is repeated 1 to 5 times, the opening size of the gauze becomes about 50 μm. By performing plating of one time, the opening size is usually reduced by about 10 to 50 μm though it depends upon the plating conditions.

The above-mentioned operation is repeated so that the opening sizes of a gauze in the area having the smallest opening size should become usually 10 to 70 μm, preferably 30 to 70 μm, particularly preferably 30 to 50 μm, and the width of the area in which the opening sizes of the gauze are thus controlled should become usually 100 to 2000 μm, preferably 250 to 1000 μm.

In the screen produced as above, the openings of the gauze are made fine so as to form a slope of a solder resist layer in the vicinity of the lead, as shown in FIG. 3.

FIG. 4 is a sectional view of a screen produced in the above manner, said view being taken on line A-A of FIG. 3. FIG. 5 is a view schematically showing stainless steel fine wires constituting the gauze 32 near the masking zone 33 in this screen and showing openings.

The gauze shown in FIG. 5 is a gauze having a stainless steel mesh size of 150 mesh. The thickness (diameter) of the stainless steel fine wire to constitute this gauze is 60 μm, and the opening size is about 109 μm. In the screen for use in the present invention, the gauze 32 corresponding to the slope 21 is exposed and plated, and then operations of masking and plating are further repeated as described above. As a result, as the masking zone 33 is approached, the wire diameters of the stainless steel fine wires become larger, and to the contrary, the opening sizes become smaller, as shown in FIG. 5. For example, the stainless steel fine wires 35-9, 35-10, 35-11 and 35-12 shown in FIG. 5 are those for constituting a usual stainless steel mesh (e.g., mesh size of 150 mesh), and they have a diameter of 60 μm. The sizes of the openings m9, m10 and m11 are each 109 μm. However, the stainless steel fine wire 35-8 has a nickel plated layer on its surface so that the wire diameter of the stainless steel fine wire 35-8 becomes larger than the wire diameter of the stainless steel fine wire 35-9, and the nickel plated layer on the stainless steel fine wire 35-7 is thicker that that on the stainless steel fine wire 35-8. Likewise, the thickness of the nickel plated layer is increased in the order of the stainless steel fine wires 35-6, 35-5, 35-4, 35-3, 35-2 and 35-1. Therefore, as the masking zone 33 is approached, the wire diameter of the stainless steel fine wire becomes larger. In the gauze 32 in which stainless steel fine wires having stepwise-changed diameters are arranged in a prescribed width, the opening sizes gradually become smaller from the opening m8, as the masking zone 33 is approached, and the size of the opening ml becomes smallest in FIG. 5. Although the stainless steel fine wires 35 are explained above with reference to FIG. 5, other stainless steel fine wires 36 which constitute the gauze 32 together with the stainless steel fine wires 35 are also subjected to plating in the same manner as described above.

By the use of the screen in which the stainless steel fine wires of the gauze have been plated in plural steps to stepwise or continuously reduce the opening sizes, a solder resist layer 20 having a slope 21 at the edge portion can be formed.

By the way, a screen can be prepared also by a direct process, an indirect process or a direct-indirect process. The film carrier tape for mounting electronic part of the present invention can be produced by the use of a screen prepared by the direct process, the indirect process or the direct-indirect process, instead of using the screen prepared by the above-described plating process.

The direct process is a process comprising applying a photosensitive resin onto a gauze 32, drying the resin, then placing a film of desired shape on a surface of the photosensitive resin layer, irradiating the layer with an ultraviolet light through the film and developing it to remove the photosensitive resin on the area corresponding to the resulting coating solution passing zone 34 and thereby form a masking zone 33. The indirect process is a process comprising applying a photosensitive resin onto a film base, exposing and developing the resin to form a desired pattern and transferring this pattern to a surface of a gauze 32. The direct-indirect process is a combination of the direct process and the indirect process, and is a process comprising bonding a photosensitive film previously prepared to a gauze 32 by the use of a solvent or an adhesive.

On the surface of the gauze 32 (the resin layer) whose opening sizes have been changed as above, a squeegee is moved to scrape down the solder resist coating solution, whereby the amount of the solder resist coating solution is changed according to the opening sizes of the gauze, and the thickness of the solder resist layer near the lead 18 can be continuously decreased toward the lead 18 as in the film carrier tape for mounting electronic part of the present invention.

By controlling the opening sizes of the gauze of the screen as described above, a slope 21 can be formed at the edge portion of the solder resist layer 20 that is in contact with the lead 18 of the film carrier tape for mounting electronic part of the present invention. In the film carrier tape for mounting electronic part of the present invention, however, the slope 21 can be formed at the edge portion of the solder resist layer 20 not by the above method but by other methods.

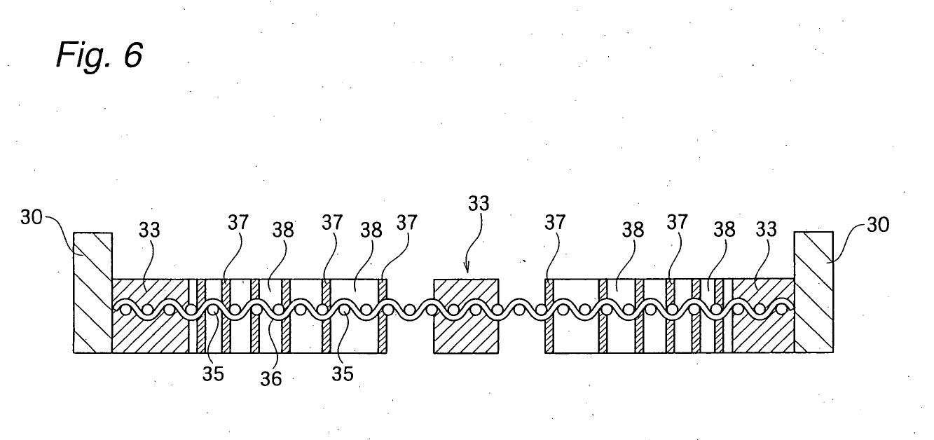

For example, by the use of a screen usually used, the amount of the solder resist coating solution fed to the gauze corresponding to the slope to be formed at the edge portion of the solder resist layer 20 is stepwise decreased, whereby the amount the solder resist coating solution that passes through the gauze can be continuously decreased to form a slope 21 of the solder resist layer 20. In this method, a surface of the gauze 32 corresponding to the slope 21 of the solder resist layer 20 is masked with a photosensitive resin, and this masking is made by a mesh masking material 37, as shown in FIG. 6. By making mesh opening size 38 of the material larger as the coating solution passing zone 34 is approached, the amount of the solder resist coating solution fed to the surface of the gauze 32 is increased. All the opening sizes of the screen used in this method are uniform, and therefore, by controlling the amount of the solder resist coating solution fed to the surface of the gauze as above, a slope 21 can be formed at the edge portion of the solder resist layer 20.

Further, through the indirect process or the direct-indirect process, a tape or a mesh capable of controlling the amount of the solder resist coating solution fed is formed, whereby the amount of the solder resist coating solution which passes through the gauze can be controlled to form a solder resist layer having a slope in the film carrier tape for mounting electronic part of the present invention.

In the film carrier tape for mounting electronic part of the present invention, the solder resist layer has a slope at the edge portion as described in detail hereinbefore, and the thickness of the solder resist layer is in the range of usually 20 to 75 μm, preferably 25 to 55 μm, except the slope. By the formation of such a solder resist layer, the wiring pattern can be surely protected. Also at the slope, the wiring pattern can be favorably protected.

The solder resist coating solution applied as above is a high-viscosity coating solution containing an organic solvent. Even if fine irregularities are produced with the changes of the coating surface attributable to diameters of the fine wires for constituting the gauze, they are made uniform by the time the solder resist coating solution is cured, and a slope is formed.

The resin contained in the solder resist coating solution is usually a thermosetting resin, and after application of the solder resist coating solution, the solvent is removed and the resin is further heated to be cured.

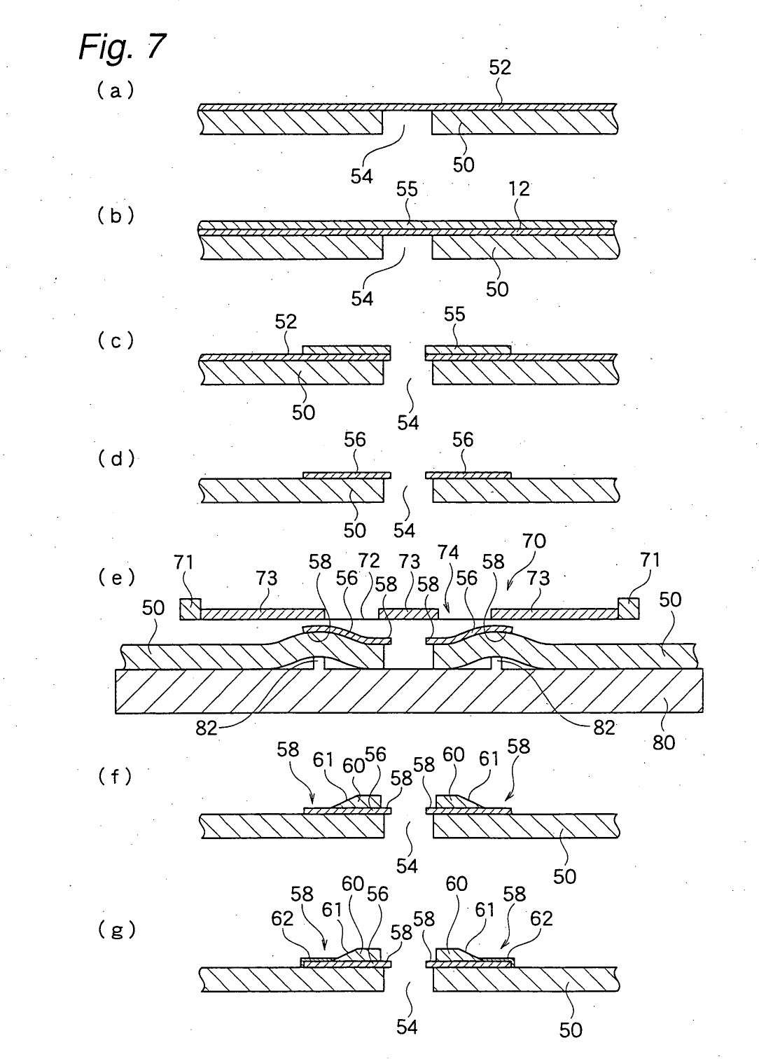

The film carrier tape for mounting electronic part of the present invention may be produced by partially pressing a film carrier against a screen, as shown in FIG. 7.

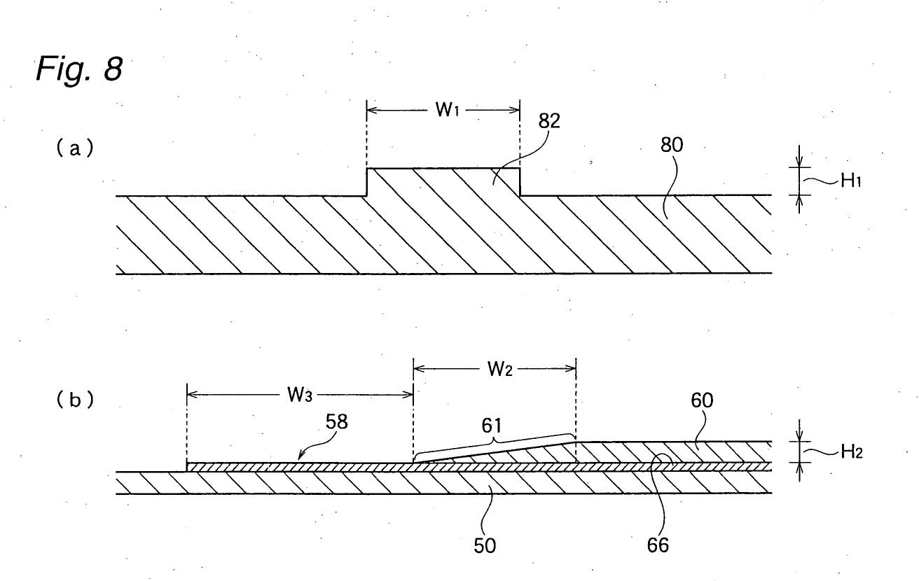

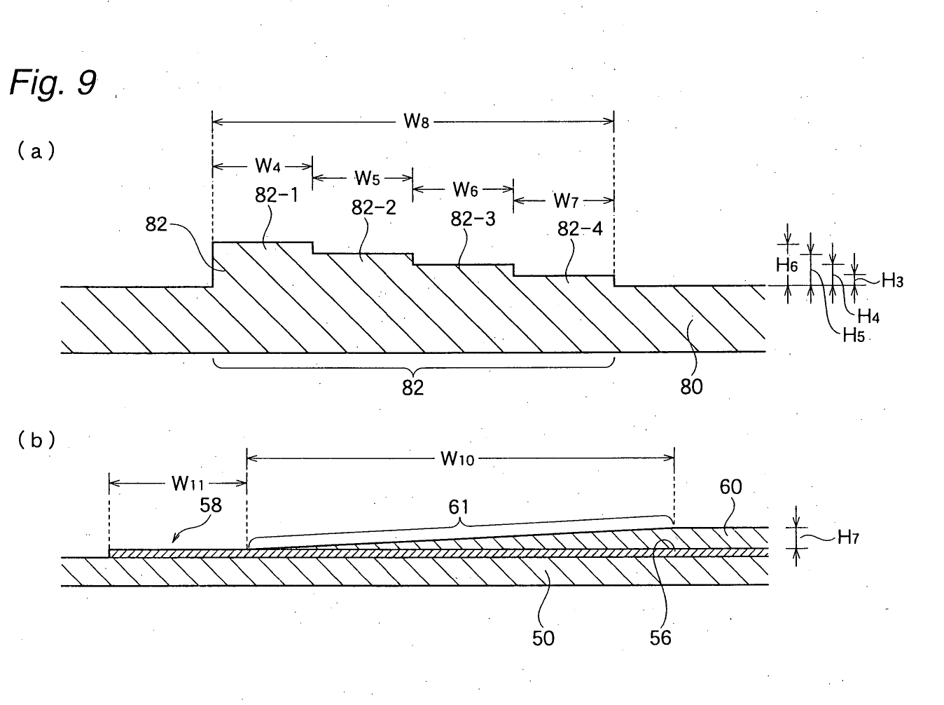

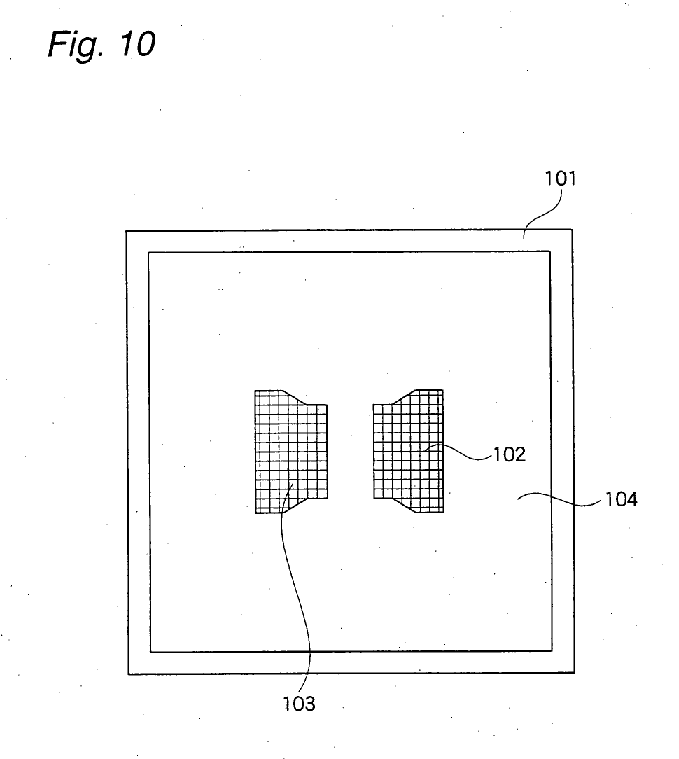

FIG. 7 is a group of sectional views to explain a process for producing a film carrier tape for mounting electronic part of the present invention, using a lengthwise (feed direction) section of a film carrier in each step of the process. FIG. 8 schematically shows a section of a coating stage having a protrusion that is used in the present invention. FIG. 9 schematically shows a section of a coating stage having a staircase protrusion that is used in the present invention.

In the process for producing a film carrier tape for mounting electronic part according to the present invention, a composite laminate having an insulating film 50 and a conductive metal layer 52 arranged on at least one surface of the insulating film 50 as shown in FIG. 7(a) is employed.

As the insulating film 50, the same synthetic resin film as previously mentioned, such as a polyimide film, can be employed. On at least one surface of the insulating film 50, the same conductive metal layer 52 as previously mentioned is formed, and in the resulting laminate, sprocket holes, device holes 54, etc. can be provided in the same manner as previously mentioned.

In the present invention, a photoresist is applied to a surface of the conductive metal layer 52 arranged on at least one surface of the insulating film 50 as shown in FIG. 7(a) to form a photoresist layer 55, as shown in FIG. 7(b). The photoresist layer is exposed by light and developed to form a desired pattern 56 composed of the photoresist, as shown in FIG. 7(c). Using the desired pattern composed of the photoresist as a masking material, the conductive metal layer 52 on the surface of the insulating film 50 is subjected to etching to form a wiring pattern 56 having a shape corresponding to the pattern, as shown in FIG. 7(d).

On a surface of the wiring pattern 56 formed as above, a solder resist layer 60 is formed except the connection portions of the lead 58. By the solder resist layer 60 thus formed, wires of the wiring pattern 56 except the lead 58 are protected.

In the present invention, a solder resist layer having a prescribed thickness ranging usually from 1 to 75 μm, preferably from 10 to 55 μm, is formed on the wiring pattern 56 which should be surely protected, similarly to the conventional solder resist layer, and in the vicinity of the lead 58 (outer lead in case of FIG. 7), a slope 61 of the solder resist layer is formed.

That is to say, a slope 61 of the solder resist layer 60, in which the thickness of the edge portion of the solder resist layer 60 is continuously decreased as the lead 58 (outer lead in case of FIG. 7) is approached, is formed, as shown in FIG. 7(g) and FIG. 8(b).

The solder resist layer 60 having such a slope 61 can be formed by coating a film carrier, which has been fed and placed on a coating stage 80 having a protrusion 82, with a solder resist coating solution through a screen 70.

The conventional screen 70 generally used comprises a frame 71 and a gauze 72 stretched on the frame 71, and the gauze 72 has a masking zone 73 to inhibit passing of a solder resist coating solution and has a coating solution passing zone 74 imparted with a desired shape by the masking zone 73.

By the use of a squeegee, the solder resist coating solution fed to the surface of the screen 70 is allowed to pass through the coating solution passing zone 74 to coat the prescribed area of the film carrier with the solder resist coating solution.

On the other hand, the film carrier to be coated with the solder resist coating solution is located and placed on the coating stage 80. The upper surface of the coating stage 80 is provided with a protrusion 82 positioned correspondingly to the edge portion of the solder resist layer to be formed. Owing to the protrusion 82, the film carrier is partially pushed up to the side of the screen 70.

The film carrier is pushed up and comes close to the screen, and as a result, the distance between the film carrier and the gauze 72 of the screen 70 at this position is decreased.

When a squeegee is moved on the screen, the gauze 72 of the screen is pushed downward. Consequently, the film carrier pushed upward by the protrusion 82 and the gauze 72 pushed downward by the squeegee are pressed against each other, and the coating space (coating thickness) for the solder resist coating solution at this position becomes extremely thin.

However, a sufficient space is ensured between the gauze 72 and the film carrier that is not pushed upward by the protrusion 82, so that the solder resist coating solution can be applied in a desired thickness.

FIG. 8(a) is a sectional view showing an example of a section of a coating stage 80 having a protrusion 82 that is used in the process for producing a film carrier tape for mounting electronic part according to the present invention. The coating stage 80 used in the present invention is provided with a protrusion 82. The height H₁ of the protrusion 82 is, for example, usually 50% to 300%, preferably 100 to 250%, of the usual thickness of the solder resist layer, and is about 10 to 200 μm. Although the width W₁ of the protrusion 82 is not specifically restricted, the width W₁ of the protrusion 82 is appropriately determined taking a width W₂ of the slope 61 to be formed, a usual height H₂ of the solder resist layer, properties of the solder resist coating solution such as viscosity, coating conditions of a coating apparatus such as coating rate, etc. into consideration.

In FIG. 8(a), if the width W₁ of the protrusion 82 is 800 μm, the slope 61 formed by the protrusion 82 can have a width W₂ of about 1000 μm after cured. The thickness (except the slope 61) of the solder resist layer 60 formed as above is in the range of usually 20 to 75 μm, preferably 25 to 55 μm, after cured.

In FIG. 8, a single protrusion 82 is provided, but the protrusion 82 employable herein is not limited thereto, and the protrusion may be in a shape of, for example, a staircase, as shown in FIG. 9. In FIG. 9(a), a section of a coating stage 80 provided with a protrusion 82 in a shape of a staircase consisting of stairs 82-1, 82-2, 82-3 and 82-4 is shown. The total width W₈ of the staircase protrusion 82 is appropriately determined taking a width W₁₀ of the slope 61 to be formed, a usual height H₇ of the solder resist layer, properties of the solder resist coating solution such as viscosity, coating conditions of a coating apparatus such as coating rate, etc. into consideration.

The height H₆ of the stair 82-1 of the protrusion 82 can be usually 50% to 300%, preferably 100% to 250%, of the usual thickness of the solder resist layer 60 to be formed. The heights of the stairs 82-2, 82-3 and 82-4 can be determined by dividing the height of the stair 82-1 by the number of stairs and subtracting the resulting value from the height of the stair 82-1 in order so that the decrease of each stair might be equal. For example, when the thickness of the ordinary solder resist layer 60 is 50 μm and the height H₆ of the protrusion 82 consisting of 4 stairs is 100 μm, the height H₆ is divided by 4, resulting in a value of 25 μm. Hence, when the height H₆ is 100 μm, the heights of the stairs are so equally decreased that the heights H₅, H₄ and H₃ become 75 μm, 50 μm and 25 μm, respectively. The protrusion may be in a shape of a continuous slope, not in a shape of a staircase.

In the staircase protrusion 82, the width of each stair can be appropriately determined. For example, when the width W₁₀ of the slope 61 after cured is set to 1200 μm, the total width W₈ of the protrusion 82 is preferably about 1000 μm, and in this case, the widths W₄, W₅, W₆ and W₇ can be each 250 μm that is a value obtained by dividing the total width W₈ (1000 μm) by the number of stairs.

In the production process of the present invention, the width W₂ or W₁₀ (after cured) of the slope of the solder resist layer where the solder resist coating thickness is continuously or stepwise decreased is in the range of usually 100 to 2000 μm, preferably 250 to 2000 μm, more preferably 300 to 2000 μm, most preferably 400 to 1000 μm, as measured from the edge of the solder resist layer.

On the upper surface of the coating stage 80 having the protrusion 82 or the staircase protrusion 82, a film carrier is fed, located and placed, then a screen is arranged on the film carrier, and a solder resist coating solution is applied. As a result, a slope 61 can be formed at the edge portion of the solder resist layer 60, as shown in FIG. 8(b) or FIG. 9(b).

In FIG. 8(b) and FIG. 9(b), numeral 58 designates an outer lead and/or inner lead, and the distance W₃, W₁₁ between the tip of the lead 58 and the slope 61 of the solder resist layer is usually 1000 to 5000 μm, without limiting thereto.

After the solder resist coating solution is applied so as to form a solder resist layer 60 having a slope 61 as described above, the solder resist coating solution is cured to form a solder resist layer 60, as shown in FIG. 7(f).

The thickness of the solder resist layer 60 is in the range of usually 20 to 75 μm, preferably 25 to 55 μm, except the slope 61. By forming the solder resist layer 60 in the above manner, the wiring pattern can be surely protected. Also at the slope 61, the wiring pattern can be favorably protected.

The position of the protrusion 82 provided on the coating stage 80 is determined by the direction of the lead 58, and the protrusion 82 may be parallel or right-angled to the moving direction of the squeegee for applying the solder resist coating solution.

The solder resist coating solution applied as above is, for example, a high-viscosity coating solution containing an organic solvent. Even if there is a difference in level on the coating surface, the surface is leveled by the time the solder resist coating solution is cured, and an almost continuous slope is formed.

The resin contained in the solder resist coating solution is usually a thermosetting resin, and after application of the solder resist coating solution, the solvent is removed and the resin is further heated to be cured.

In FIG. 7, a slope where the coating thickness is continuously decreased is provided on the outer lead side of the solder resist layer, but as a matter of course, such a slope can be provided also on the inner lead side.

After the solder resist layer is formed as above, a plated layer 22 or 62 is formed on the lead exposed from the solder resist layer, as shown in FIG. 1(f) or FIG. 7(g).

Examples of the plated layers 22 and 62 include a tin plated layer, a gold plated layer, a nickel plated layer, a nickel-gold plated layer, a solder plated layer, a zinc plated layer and a tin-bismuth plated layer. Such a plated layer may be formed by any of electroless plating and electroplating. In case of, for example, tin plating, the thickness of the plated layer is in the range of 0.1 to 1.0 μm, preferably 0.3 to 0.6 μm.

Although an embodiment wherein the plated layer is formed after the formation of the solder resist layer is described above, it is also possible that a thin plated layer is formed before the formation of the solder resist layer, then the solder resist layer is formed, and a plated layer is formed again. By performing preplating, formation of a solder resist layer and plating in this manner, dissolution of the wiring pattern in the plating solution can be prevented even if the plating solution comes down onto the lower surface of the solder resist layer. This method is particularly useful for forming a tin plated layer.

In the film carrier tape for mounting electronic part of the present invention, the solder resist layer has, at its edge portion, a slope where the coating thickness of the solder resist layer is continuously decreased toward the lead, and therefore, at this edge portion, the thickness of the solder resist layer does not hinder electrical connection of the lead. Accordingly, the film carrier tape for mounting electronic part of the present invention has excellent electrical connection stability.

### EFFECT OF THE INVENTION

In the film carrier tape for mounting electronic part of the present invention, the solder resist layer is made thin in the vicinity of the connecting portion of the lead to form a slope. Therefore, even if an electronic part slightly deviate to make a part of an electrode, which is to be electrically connected to the connecting portion of a lead of the film carrier tape, overlap the solder resist layer, connection of the lead is not hindered by the thickness of the solder resist layer. Consequently, satisfactory connection reliability can be ensured.

The solder resist layer having such a slope can be formed by application of a solder resist coating solution one time, and therefore, productivity of the film carrier tape of the present invention is very excellent.

In the screen for solder resist coating that is favorably used for producing the film carrier tape for mounting electronic part, metal fine wires constituting a gauze are plated to control opening sizes of the gauze, whereby the amount of the solder resist coating solution that passes the gauze can be controlled. By the use of the screen for solder resist coating, the film carrier tape for mounting electronic part of the present invention can be efficiently produced.

In the process for producing the film carrier tape of the present invention, further, a film carrier is partially pressed against the screen to decrease the coating space for the solder resist coating solution and thereby form a slope in the solder resist layer. Hence, the film carrier tape for mounting electronic part of the present invention can be efficiently produced.

### EXAMPLES

The film carrier tape for mounting electronic part of the present invention, the process for producing the film carrier tape and the screen for solder resist coating are further described with reference to the following examples, but it should be construed that the invention is in no way limited to those examples.

### Example 1

A gauze having a mesh size of 150 mesh constituted of stainless steel fine wires having a wire diameter of 60 μm was stretched on an aluminum frame to produce a screen for solder resist coating.

The gauze of the screen was coated with a photosensitive resin, and the resin was exposed by light and developed in the form of a prescribed pattern to form a coating solution passing zone through which a solder resist coating solution was to pass.

Then, the edge portion of the coating solution passing zone of the screen on the side where an outer lead (terminal) of a film carrier tape was to be formed was masked in a width of 170 μm, and the coating solution passing zone was coated with a resin. After the resin was cured, the masking material was removed, and the screen was immersed in an electroless nickel plating solution to form a nickel plated layer around each stainless steel fine wire having a wire diameter of 60 μm present in the above-mentioned 170 μm-width area.

After the stainless steel fine wires present in the 170 μm-width area were subjected to nickel plating of the first time as above, the screen was taken out of the plating solution, and the resin coating was removed from the coating solution passing zone.

Then, the edge portion of the coating solution passing zone of the screen on the side where an outer lead of a film carrier tape was to be formed was masked in a width of 340 μm (170 μm×2=340 μm), and the coating solution passing zone was coated with a resin. After the resin was cured, the masking material was removed, and the screen was immersed in an electroless nickel plating solution to form a nickel plated layer around each stainless steel fine wire present in the above-mentioned area of a width of 340 μm. As a result, the screen fine wires present in the 170 μm-width area from the edge of the coating solution passing zone had been nickel plated two times, and the screen fine wires present in the 170 μm-width area located inside the above 170 μm-with area had been nickel plated one time.

After the stainless steel wires present in the 340 μm-width area were subjected to nickel plating as above, the screen was taken out of the plating solution, and the resin coating was removed from the coating solution passing zone.

Then, the edge portion of the coating solution passing zone of the screen on the side where an outer lead of a film carrier tape was to be formed was masked in a width of about 500 μm (170 μm×3=510 μm), and the coating solution passing zone was coated with a resin. After the resin was cured, the masking material was removed, and the screen was immersed in an electroless nickel plating solution to form a nickel plated layer around each stainless steel fine wire present in the above-mentioned area of a width of about 500 μm. As a result, the screen fine wires present in the 170 μm-width area from the edge of the coating solution passing zone had been nickel plated three times, the screen fine wires present in the 170 μm-width area located inside the above 170 μm-with area had been nickel plated two times, and the screen fine wires present in the 170 μm-width area located further inside the above 170 μm-with area had been nickel plated one time.

After the stainless steel fine wires present in the area of a width of about 500 μm were subjected to nickel plating as above, the screen was taken out of the plating solution, and the resin coating was removed from the coating solution passing zone.

By stepwise carrying out nickel plating three times as described above, the stainless steel fine wires present in the area of a width of 170 μm from the edge of the coating solution passing zone had been nickel plated three times, and the opening size in this area was 50 μm. As the center of the coating solution passing zone was approached, the opening sizes became larger stepwise, and the opening size in the area protected by the resin coating and subjected to no plating was 109 μm.

The screen having been nickel plated in the above manner is schematically shown in FIG. 3, in which numeral 34 designates a coating solution passing zone. By the use of the screen having such a coating solution passing zone, an outer lead that is a terminal designated by numeral 18 in FIG. 2 is exposed by 2.0 mm, and from a rear end of the exposed outer lead, a wiring pattern 17 is coated with a solder resist slope 21 (length: about 500 μm), and the wiring pattern 17 is further coated with a solder resist layer 20 having a thickness of 44 μm continued from the solder resist slope 21 (length: about 500 μm). Using the screen for solder resist coating produced as above, a solder resist coating solution was applied to produce a film carrier tape for mounting electronic part.

More specifically, a surface (copper layer surface) of a composite film consisting of a polyimide film having an average thickness of 50 μm and a copper layer having an average thickness of 25 μm laminated on one surface of the polyimide film as shown in FIG. 1(a) was coated with a photoresist, as shown in FIG. 1(b). The photoresist was exposed by light and developed to form a pattern composed of the cured photoresist, as shown in FIG. 1(c).

After the pattern was formed as above, the copper layer was subjected to etching using the pattern as a masking material to form a wiring pattern, as shown in FIG. 1(d). Both end portions of the wiring pattern thus formed are connecting leads.

Then, a solder resist coating solution was applied onto the wiring pattern using the above-prepared screen for solder resist coating, as shown in FIG. 1(e). The screen used herein was such a screen that the coating thickness (thickness after cured) of the solder resist coating solution on the wiring pattern of the film carrier tape for mounting electronic part became 44 μm, and in the area of about 500 μm from the exposed lead (2.0 mm) of the wiring pattern, the opening sizes of the gauze were gradually reduced, and the opening size in the vicinity of the tip of the masking zone formed in the screen finally became 50 μm. By the use of such a screen, the solder resist coating solution could be applied so that the coating thickness of the solder resist was continuously decreased toward the outer lead.

Then, the solder resist was cured, and thereafter the film carrier tape for mounting electronic part was continuously fed to an electroless tin plating bath to form a tin plated layer having an average thickness of 0.45 μm on the lead exposed from the solder resist layer.

Using the film carrier tape for mounting electronic part, a mounting test was carried out. That is to say, an anisotropic conductive film (ACF) was superposed on the edge of the solder resist layer of the film carrier, followed by a connection test. As a result, any defective caused by bonding failure was not produced.

In case of a conventional film carrier tape for mounting electronic part (solder resist coating thickness is entirely uniform and 44 μm), fraction defective due to bonding failure sometimes reaches 1 to 20%, and the film carrier tape having such high fraction defective cannot be supplied as a manufactured article.

According to the present invention, no defective is produced, though defectives are produced in case of a conventional film carrier tape, and the film carrier tape produced by the present invention can be used without any problem similarly to ordinary manufactured articles.

### Example 2

A surface (copper layer surface) of a composite film consisting of a polyimide film having an average thickness of 50 μm and a copper layer having an average thickness of 25 μm laminated on one surface of the polyimide film as shown in FIG. 7(a) was coated with a photoresist, as shown in FIG. 7(b). The photoresist was exposed by light and developed to form a pattern composed of the cured photoresist, as shown in FIG. 7(c).

After the pattern was formed as above, the copper layer was subjected to etching using the pattern as a masking material to form a wiring pattern, as shown in FIG. 7(d). Both end portions of the wiring pattern thus formed are connecting leads.

Then, a solder resist coating solution was applied onto the wiring pattern using the conventional screen for solder resist coating, as shown in FIG. 7(e).

That is to say, the film carrier tape was placed on a coating stage provided with a protrusion having a width W₁ of 800 μm and a height H₁ of 100 μm, as shown in FIG. 8(a), and a solder resist coating solution was applied onto the film carrier tape using the screen for solder resist coating.

Then, the solder resist coating solution was cured. By the use of the coating stage provided with the protrusion, the outer lead W₃ was exposed by about 2000 μm, and from this position a slope having a width W₂ of 1000 μm was formed to form a solder resist layer having a height H₂ of 50 μm, as shown in FIG. 8(b).

Then, the film carrier tape for mounting electronic part-was continuously fed to an electroless tin plating bath to form a tin plated layer having an average thickness of 0.45 μm on the lead exposed from the solder resist layer.

Using the film carrier tape for mounting electronic part, a mounting test was carried out. That is to say, an anisotropic conductive film (ACF) was superposed on the edge of the solder resist layer of the film carrier, followed by a connection test. As a result, any defective caused by bonding failure was not produced.

In case of a conventional film carrier tape for mounting electronic part (solder resist coating thickness is entirely uniform and 44 μm), fraction defective due to bonding failure sometimes reaches 1 to 20%.

### Example 3

A film carrier tape for mounting electronic part was produced in the same manner as in Example 2, except that such a staircase coating stage as shown in FIG. 9(a) was used as the coating stage.

In the staircase coating stage used herein, the widths W₄, W₅, W₆ and W₇ of the stairs were each 250 μm, the total width W₈ was 1000 μm, the height H₆ was 100 μm, the height H₅ was 75 μm, the height H₄ was 50 μm, and the height H₃ was 25 μm. Using such a staircase coating stage, a solder resist coating solution was applied, and then the solder resist was cured. By the use of the staircase coating stage, the outer lead W₁₁ was exposed by about 2000 μm, and from this position a slope having a width W₁₀ of 1200 μm was formed to form a solder resist layer having a height H₇ of 50 μm, as shown in FIG. 9(b). Thereafter, the film carrier tape for mounting electronic part was continuously fed to an electroless tin plating bath to form a tin plated layer having an average thickness of 0.45 μm on the lead exposed from the solder resist layer.

Using the film carrier tape for mounting electronic part, a mounting test was carried out. That is to say, an anisotropic conductive film (ACF) was superposed on the edge of the solder resist layer of the film carrier, followed by a connection test. As a result, any defective caused by bonding failure was not produced.

1. A film carrier tape for mounting an electronic part, comprising an insulating film, a wiring pattern formed on a surface of the insulating film and a solder resist layer formed on the wiring pattern except connecting lead portions of the wiring pattern, wherein the solder resist coating thickness at the edge portion of the solder resist layer is continuously decreased toward the tip of the edge portion.

2. The film carrier tape for mounting an electronic part as claimed in claim 1, wherein the solder resist coating thickness is continuously decreased at the edge portion of the solder resist layer in a width of 100 to 2000 μm.

3. A process for producing a film carrier tape for mounting an electronic part, comprising forming a desired wiring pattern on a surface of an insulating film and then forming a solder resist layer on the wiring pattern except lead portions of the wiring pattern, wherein formation of the solder resist layer is carried out by the use of a screen for solder resist coating in which opening sizes at the edge portion of a coating solution passing zone are reduced stepwise or continuously.

4. The process for producing a film carrier tape for mounting an electronic part as claimed in claim 3, wherein the screen comprises a gauze constituted of fine metal wires and the smallest opening size of the gauze is in the range of 30 to 70 μm.

5. A screen for solder resist coating, comprising a frame and a gauze stretched on the frame and being produced in such a manner that the amount of a solder resist coating solution which passes through the gauze should be decreased stepwise or continuously toward a masking zone provided on the gauze.

6. The screen for solder resist coating as claimed in claim 5, wherein the gauze has an area in which opening sizes are changed stepwise or continuously.

7. The screen for solder resist coating as claimed in claim 5, wherein control of the opening sizes of the gauze is carried out by forming metal plated layers on fine metal wires of the gauze in such a manner that the opening sizes should be stepwise reduced.

8. A process for producing a film carrier tape for mounting an electronic part, comprising applying a solder resist coating solution onto a wiring pattern formed on a surface of an insulating film except connecting lead portions of the wiring pattern through a screen to form a solder resist layer, wherein the solder resist coating solution is applied with pressing a film carrier against the screen so as to decrease a coating weight of the solder resist coating solution continuously or stepwise toward the tip of the edge portion of the resulting solder resist layer.

9. The process for producing a film carrier tape for mounting an electronic part as claimed in claim 8, wherein application of the solder resist coating solution is carried out by pressing the film carrier against the screen by means of a protrusion provided on a coating stage for placing the film carrier.

10. The process for producing a film carrier tape for mounting an electronic part as claimed in claim 8, wherein the protrusion is in a shape of a staircase.

11. The process for producing a film carrier tape for mounting an electronic part as claimed in claim 8, wherein the solder resist coating thickness is continuously or stepwise decreased at the edge portion of the solder resist layer in a width of 100 to 2000 μm.

12. The process for producing a film carrier tape for mounting an electronic part as claimed in claim 99, wherein the protrusion provided on the coating stage in order to press the film carrier against the screen has a height of 10 to 200 μm.

13. The process for producing a film carrier tape for mounting an electronic part as claimed in claim 9, wherein the protrusion is in a shape of a staircase.

14. The process for producing a film carrier tape for mounting an electronic part as claimed in claim 10, wherein the protrusion provided on the coating stage in order to press the film carrier against the screen has a height of 10 to 200 μm.
